(19) United States
(12) Patent Application Publication
(10) Pub. No.: US 2017/0269939 A1
(43) Pub. Date: Sep. 21, 2017

(54) SELECTION OF AN OPERATING SYSTEM

(71) Applicant: Hewlett-Packard Development Company, L.P., Houston, TX (US)

(72) Inventors: Chi SO, Spring, TX (US); Nam NGUYEN, Houston, TX (US); Robert Scott WRIGHT, Sprinq, TX (US)

(21) Appl. No.: 15/506,002

(22) PCT Filed: Aug. 25, 2014
(86) PCT No.: PCT/US2014/052565

§ 371 Date: Feb. 23, 2017

(51) Int. Cl. G06F 9/44; H03K 17/00

(52) U.S. Cl. CPC G06F 9/441; G06F 9/4418; H03K 17/002

(57) ABSTRACT

Examples of a system and method are disclosed herein. An example of the system includes a first computer having a port and a first operating system to execute on the first computer. The system also includes a second computer coupled to the port of the first computer to receive power from the first computer, the second computer having a second operating system to simultaneously execute on the second computer. The system additionally includes a circuit to selectively switch between a first context supported by the first operating system of the first computer and a second context supported by the second operating system without waiting to save the first and second contexts.

### BACKGROUND

Consumers appreciate flexibility and ease of use in their devices. They also appreciate the ability to use their devices in a way which saves them time. Designers and manufacturers of these devices may, therefore, endeavor to create and supply solutions that are directed to these objectives.

### BRIEF DESCRIPTION OF THE DRAWINGS

The following detailed description references the drawings, wherein:

FIG. 1 is an example of a system in accordance with an implementation.

FIG. 2 is, an example of an additional element of the system of FIG. 1 in accordance with an implementation.

FIG. 3 is another example of additional elements of the system of FIG. 1 in accordance with an implementation.

FIG. 4 is a further example of additional elements of the system of FIG. 1 in accordance with an implementation.

FIG. 5 is yet a further example of additional elements of the system of FIG. 1 in accordance with an implementation.

FIG. 6 is an example of another system in accordance with an implementation.

FIG. 7 is an example of additional elements of the system of FIG. 6 in accordance with, an implementation.

FIG. 8 is another example of additional elements of the system of FIG. 6 in accordance with an implementation.

FIG. 9 is a further example, of additional elements of the system of FIG. 6 in accordance with an implementation.

FIG. 10 is yet a further example of additional elements of the system of FIG. 6 in accordance with an implementation.

FIG. 11 is still yet a further example of additional elements of the system of FIG. 6 in accordance with an implementation.

FIG. 12 is an example of a method in accordance with an implementation.

FIG. 13 is an example of additional elements of the method of FIG. 12 in accordance with an implementation.

### DETAILED DESCRIPTION

Some applications, games or other programs used on a computer may require different operating systems. For example, an application may require one operating system to run or execute, while a game may require a different operating system to run or execute.

One way in which this may be managed is to utilize a dual-booting computer which requires a user to choose which operating system to boot during start-up or initialization of the computer. The chosen operating system cannot be changed without rebooting the computer which requires time and effort on the part of the user. For example, a user may have to save his or her existing work and exit an application before rebooting. The rebooting itself also takes time. As another example, a user may have to interrupt in-progress activities, such as a download, and then reboot his or her computer.

Another way in which this may be managed is to sequentially boot both operating systems into memory of a computer and have the basic input and output system (BIOS) of the computer direct control to the desired operating system. Switching between operating systems is possible, but it takes time to accomplish because the currently executing or running operating system needs to be halted and the execution or running switched to the other operating system. This can be slow and reliability may be impacted. For example, if an application supported by or associated with one operating system stops working or otherwise inhibits the use of a computer, then both operating systems will be affected because one computer is running both operating systems.

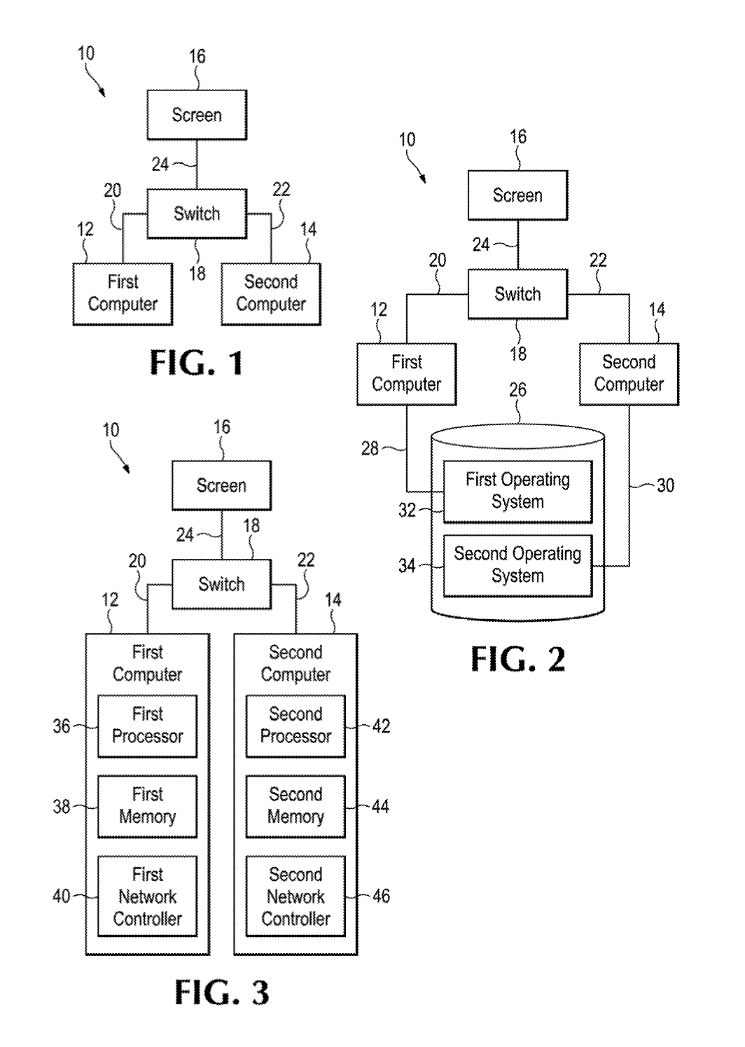

Example implementations directed to utilization of multiple operating systems to support a variety of different applications, games, and other programs are shown in FIGS. 1-13. These example implementations illustrated in FIGS. 1-13 also attempt to address the above-described potential technical challenges associated with other possible approaches to utilization of multiple operating systems.

As used herein, the term “computer” represents, but is not necessarily limited to, a general purpose device or machine that can be programmed to carry out a set of operations. Examples of a computer include, but are not necessarily limited to, a desktop personal computer (PC), a server, a notebook personal computer (PC), a tablet, smartphone, and a personal digital assistant. As used herein, “operating system” represents, but is not necessarily limited to, computer readable instructions that manage a computer and provide common services for applications, games or other programs such as recognizing commands from input devices, sending output to at least one display or screen, managing files and directories on storage devices, and controlling peripheral devices.

As used herein, the term “processor” represents, but is not necessarily limited to, an instruction execution system such as a computer-based system, an application specific integrated circuit (ASIC), a hardware and or computer-readable instruction system, or any combination thereof, that can fetch or obtain the logic from a computer-readable non-transitory storage medium and execute the instructions contained thereon. “Processor” can also include any controller, state-machine, microprocessor, logic control circuitry, cloud-based utility, service or feature, any other analogue, digital and/or mechanical implementation thereof, or any combination of the forgoing. A processor may be a component of a distributed system.

As used herein, the term “distributed system” represents, but is not necessarily limited to, multiple processors and computer-readable non-transitory storage media in different locations or systems that communicate via a network, such as the cloud. As used herein, the term “cloud” represents, but is not necessarily limited to, computing resources (hardware and/or computer-readable instructions) that are delivered as a service over a network (such as the internet).

As used herein, the term “computer-readable non-transitory storage medium” represents, but is not necessarily limited to, any medium that can contain, store, retain, or maintain programs, code, scripts, information, and/or data. A computer-readable non-transitory storage medium may include any one of many physical media such as, for example, electronic, magnetic, optical, electromagnetic, or semiconductor media. A computer-readable non-transitory storage medium may be a component of a distributed system. More specific examples of suitable computer-readable non-transitory storage media include, but are not limited to, a magnetic computer diskette such as floppy diskettes or hard drives, magnetic tape, a read-only memory (ROM), an erasable programmable read-only memory (EPROM), a flash drive or memory, a compact disc (CD), a digital video disk (DVD), or a memristor.

As used herein, the term “circuit” represents, but is not necessarily limited to, an interconnection of elements such as, for example, resistors, inductors, capacitors, voltage sources, current sources, transistors, diodes, application specific integrated circuits (ASICs), processors, controllers, switches, transformers, gates, timers, relays, multiplexors, connectors, comparators, amplifiers, filters, and/or modules having these elements that allow operations to be performed such as signal amplification, filtering or modification, computations, regulation, rectification selection modulation, or multiplexing. A circuit may utilize constant, alternating, continuous, or discrete signals, as well as any combination thereof.

As used herein, “port” represents, but is not necessarily limited to, an interface between a computer and another device. This interface may include a physical coupling or connection, an electrical coupling or connection, a magnetic coupling or connection, a transfer of signals, and/or a transfer of power. A computer may have more than one port and these ports may have the same or different interfaces. Additionally, the interface can be wired, wireless, or a combination of the two. Examples of a port include, but are not necessarily limited to, Universal Serial Bus (USB), Serial Connect Serial Interface (SCSI), Ethernet, Firewire, and Video Graphics Adapter (VGA).

As used herein, the term “memory” represents, but is not necessarily limited to, a device to store data such as a computer-readable non-transitory storage medium. As used herein, the term “context” represents, but is not necessarily limited to, a set of data used by a task or process that needs to be saved to allow the task or process to be interrupted at a giver time and subsequently continued at a later time at the point f original interruption. As used herein, the terms “include”, “includes”, “including”, “have”, “has”, “having” and variations thereof, mean the same as the terms “comprise”, “comprises”,and “comprising”, or appropriate variations thereof.

An example of a system 10 is shown in FIG. 1. As can be seen in FIG. 1, system 10 includes a first computer 12 that has a first operating system that executes or runs on first computer 12. System 10 also includes a second computer 14 that is physically separate from first computer 12 and that has a second operating system that executes or runs on second computer 14. As can also be seen in FIG. 1, system 10 includes a screen 16 to display information (e.g., data, graphics, photos and/or video) and a switch 18 coupled to first computer 12, as generally indicated by line 20, second computer 14, as generally indicated by line 22, and screen 16, its generally indicated by line 24.

Switch 18 selectively connects computer 12 to screen 16 to display information from the first operating system of first computer 12 on screen 16 without waiting to load the first operating system on first computer 12 or second computer 14 to screen 16 to display information from the second operating system of second computer 14 on screen 16 without waiting to load the second operating system on second computer 14. This helps to avoid the above-described switching or selection challenges (e.g., time delay and reliability) associated with other systems that utilize multiple operating systems.

An example of an additional element of system 10 in accordance with an implementation is shown in FIG. 2. As can be seen in FIG. 2, system 10 may additionally include a storage device 26 coupled to first computer 12, as generally indicated by line 28, and second computer 14, as generally indicated by line 30. As can additionally be seen in FIG. 2, first operating system 32 and second operating system 34 are both loaded on storage device 26. In this way, storage device 26 provides a single, shared device on which respective first and second operating systems 32 and 34 may stored, as well as any other data that may be needed by first computer 12 and/or second computer 14. It is to be understood, however, that in other implementations of system 10, first computer 12 and second computer 14 may each have a separate storage device with first operating system 32 loaded on the storage device of first computer 12 and second operating system 34 loaded on the separate storage device of second computer 14.

Another example of additional elements of system 10 in accordance with an implementation is shown in FIG. 3. As can be seen in FIG. 3, first computer 12 may include a first processor 36, a first memory 38, and a first network controller 40. As can also be seen in FIG. 3, second computer 14 may include a second processor 42, a second memory 44, and a second network controller 46. Although not shown in FIG. 3, it is to be understood that first computer 12 and/or second computer 14 may include additional components as well such as, for example, a graphics controller.

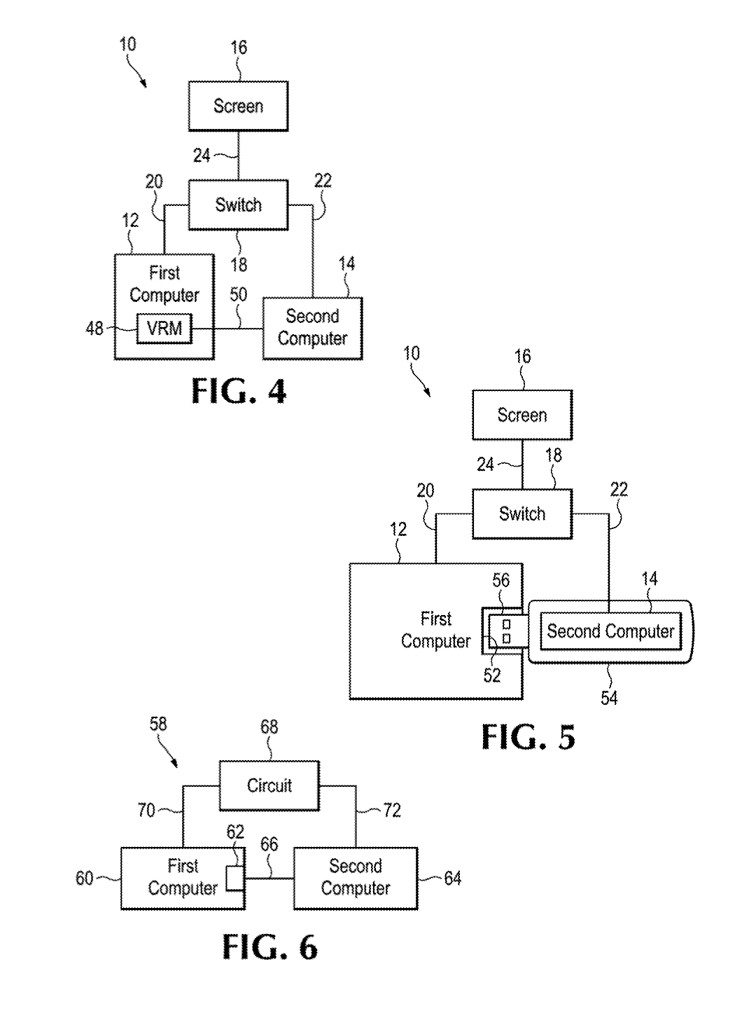

A further example of additional elements of system 10 in accordance with an implementation is shown in FIG. 4. As can be seen in FIG. 4, first computer 12 may include a voltage regulator module 48. As can also be seen in FIG. 4, voltage regulator module 48 is coupled to second computer 14, as generally indicated by line 50, to supply power to second computer 14. Voltage regulator module 48 may receive power from an external power supply (not shown in FIG. 4) which is plugged into a socket (e.g., wall outlet) and may supply direct current (DC) and/or alternating current (AC) power to first computer 12 and second computer 14. It is to be understood that in other implementations of system 10, second computer 14 may have a separate voltage regulator module (not shown in FIG. 4) instead of receiving power from voltage regulator module 48.

Yet a further example of additional elements of system 10 in accordance with an implementation is shown in FIG. 5. As can be seen in FIG. 5, first computer 12 may include a port 52. As can also be seen in FIG. 5, second computer 14 may include a housing 54 in which second computer 14 is disposed. Housing 54 includes a plug 56 to mechanically and electrically connect to first computer 12 via port 52. In the example implementation shown in FIG. 5, second computer 14, housing 54, and plug 56 together form a Universal Serial Bus (USB) module that connects to port 52 which is a Universal Serial Bus (USB) port.

An example of another system 58 in accordance with an implementation is shown in FIG. 6. As can be seen in FIG. 6, system 58 includes a first computer 60 that includes a port 62 and that has a first operating system that executes or runs on first computer 60. System 58 also includes a second computer 64 coupled to port 62 of first computer 60, as generally indicated by line 66, to receive power from first computer 60. Second computer 64 includes a second operating system that simultaneously executes or runs on second computer 64.

As can also be seen in FIG. 6, system 58 includes a circuit 68 coupled to first computer 60, as generally indicated by line 70, and to second computer 64, as generally indicated by line 72. Circuit 68 allows a user of system 58 to selectively switch between a first context supported by the first operating system of first computer 60 and a second context supported by the second operating system of second computer 64 without waiting for the first context and second context to be saved for subsequent retrieval. This helps to avoid the above-described switching or selection challenges (e.g., time delay and reliability) associated with other systems that utilize multiple operating systems.

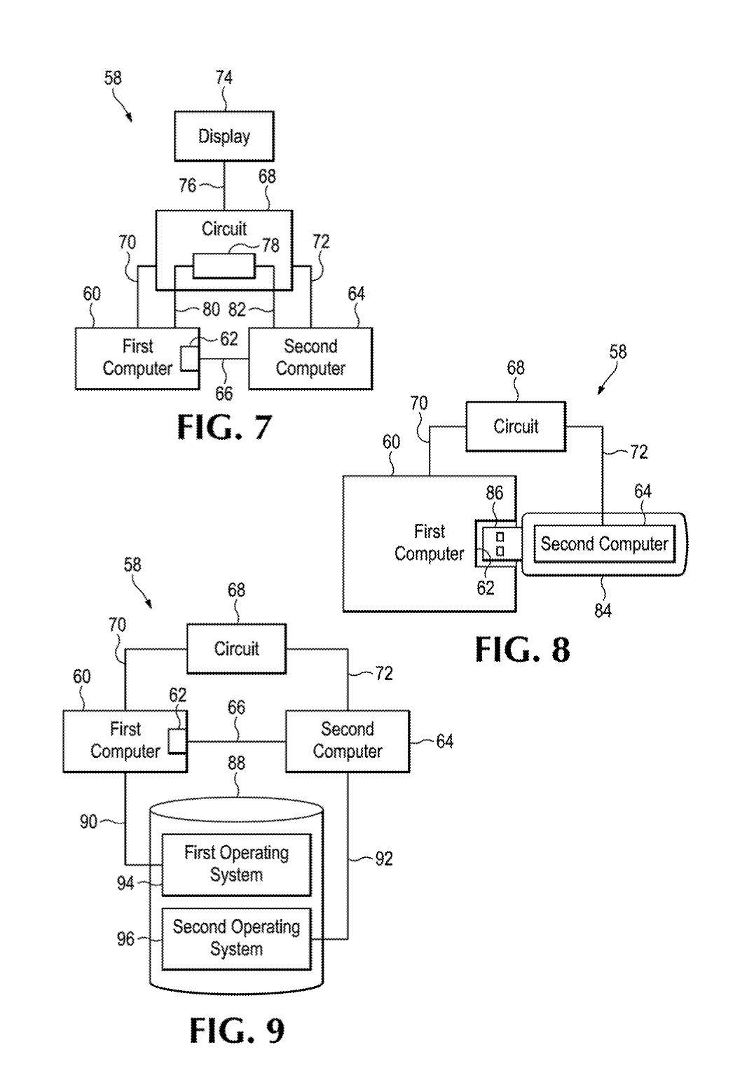

An example of additional elements of system 58 in accordance with an implementation is shown in FIG. 7. As can be seen in FIG. 7, system 58 may include a display 74 coupled to circuit 68, as generally indicated by line 76. As can also be seen in FIG. 7, circuit 68 may include a component 78 coupled to first computer 60, as generally indicated by line 80, and second computer 64, as generally indicated by line 82. Component 78 of circuit 68 allows a user of system 58 to selectively switch between a first video stream form the first operating system for viewing on display 74 and a second video stream from the second operating system for viewing on display 74. Component 78 of circuit 68 may include a single circuit element or multiple circuit elements.

Another example of additional elements of system 58 in accordance with an implementation is shown in FIG. 8. As can be seen in FIG. 8, second computer 64 may include a housing 84 in which second computer 64 is disposed. Housing 84 includes a plug 86 to mechanically and electrically connect to first computer 60 via port 62. In the example implementation shown in FIG. 8, second computer 64, housing 84, and plug 86 together form a Universal Serial Bus (USB) module that connects to port 62 which is a Universal Serial Bus (USB) port.

A further example of additional elements of system 58 in accordance with an implementation is shown in FIG. 9. As can be seen in FIG. 9, system 58 may additionally include a storage de ice 88 coupled to first computer 60, as generally indicated line 90, and by second computer 64, as generally indicated by line 92. As can additionally be seen in FIG. 9, first operating system 94 and second operating system 96 are both loaded on storage device 88. In this way, storage device 88 provides a single, shared device on which respective first and second operating systems 94 and 96 may stored, as well as any other data that may be needed by first computer 60 and/or second computer 64. It is to be understood, however, that in other implementations of system 58, first computer 60 and second computer 64 may each have a separate storage device with first operating system 94 loaded on the storage device of first computer 60 and second operating system 96 loaded on the separate storage device of second computer 64.

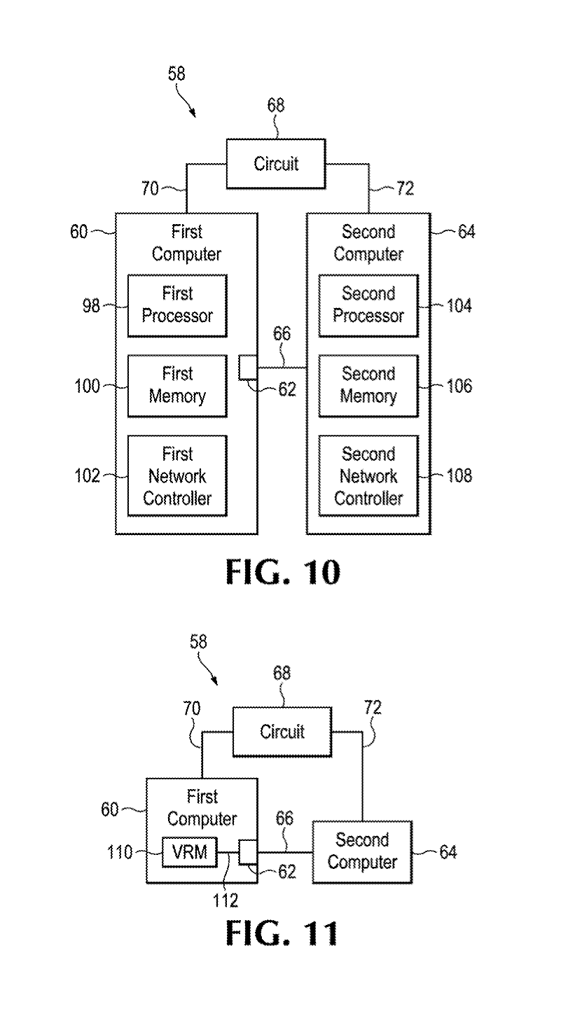

Yet a further example of additional elements of system 58 in accordance with an implementation is shown in FIG. 10. As can be seen in FIG. 10, first computer 60 may include a first processor 98, a first memory 100, and a first network controller 102. As can also be seen in FIG. 3, second computer 64 may include a second processor 104, a second memory 106, and a second network controller 108. Although not shown in FIG. 10, it is to be understood that first computer 60 and/or second computer 62 may include additional components as well such as, for example, a graphics controller.

Still yet a further example of additional elements of system 58 in accordance with an implementation is shown in FIG. 11. As can be seen in FIG. 11, first computer 60 may include a voltage regulator module 110. As can also be seen in FIG. 11, voltage regulator module 110 is coupled to second computer 64, as generally indicated by line 112, to supply power to second computer 64. Voltage regulator module 110 may receive power from an external power supply (not shown in FIG. 11) which is plugged into a socket (e.g., wall outlet) and may supply direct current (DC) and/or alternating current (AC) power to first computer 60 and second computer 64, It is to be understood that in other implementations of system 58, second computer 64 may have a separate voltage regulator module (not shown in FIG. 11) instead of receiving power from voltage regulator module 110.

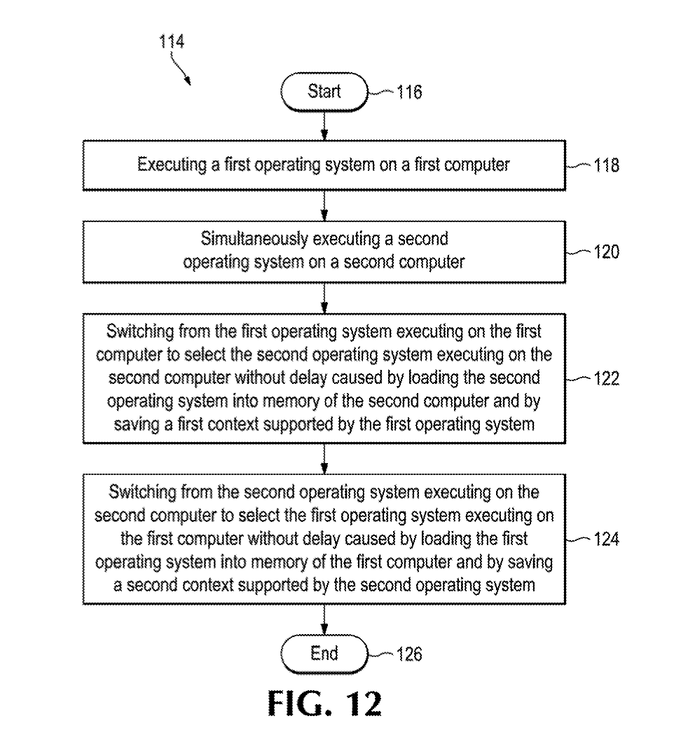

An example of a method 114 is shown in FIG. 12. Method 114 may be implemented by various devices, apparatuses and systems, such as, for example, systems 10 and/or 58. As can be seen in FIG. 12, method 114 sums 116 by executing a first operating system on a first computer, as indicated by block 118, and simultaneously executing a second operating system on a second computer, as indicated by block 120. Method 114 continues by switching from the first operating system executing on the first computer to select the second operating system executing on the second computer without delay caused by loading the second operating system into memory of the second computer and by saving a first context supported by the first operating system, as indicated by block 122. This helps to avoid the above-described switching or selection challenges (e.g., time delay and reliability) associated with other methods that utilize multiple operating systems.

Method 114 may then continue by switching from the second operating system executing on the second computer to select the first operating system executing on the first computer without delay caused by loading the first operating system into memory of the first computer and by saving a second context supported by the second operating system, as indicated by block 124. This also helps to avoid the above-described switching or selection challenges (e.g., time delay and reliability) associated with other methods that utilize multiple operating systems. Method 114 may then end 126.

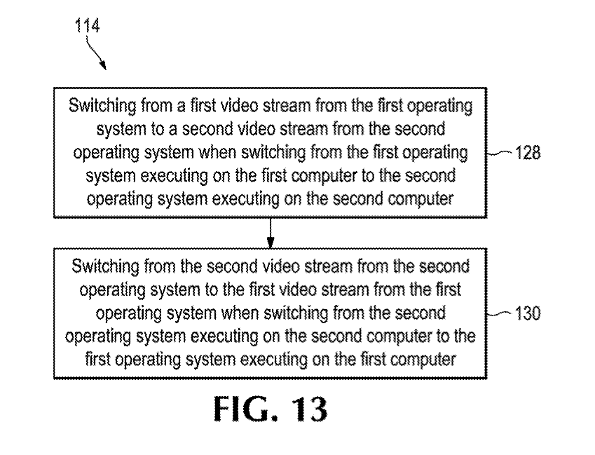

An example of additional elements of method 114 in accordance with an implementation are shown in FIG. 13. As can be seen in FIG. 13, method may additionally include switching from a first video stream from the first operating system to a second video stream from the second operating system when switching from the first operating system executing on the first computer to the second operating system executing on the second computer, as indicated by block 128. In such cases, method 114 also includes switching from the second video stream from the second operating system to the first video stream from the first operating system when switching from the second operating system executing on the second computer to the first operating system executing on the first computer, as indicated by block 130.

Although several drawings have been described and illustrated in detail, it is to be understood that the same are intended by way of illustration and example. These examples are not intended to be exhaustive or to be limited to the precise form disclosed. Modifications, additions, and variations may well be apparent.

Additionally, reference to an element in the singular is not intended to mean one, unless explicitly so stated, but rather means at least one. Furthermore, unless specifically stated, any method elements, flowchart elements and/or instructions of a machine-readable non-transitory storage medium are not limited to the sequence or order described and illustrated. Moreover, no element or component is intended to be dedicated to the public regardless of whether the element or component is explicitly recited in the following claims.

What is claimed is:

1. A system, comprising:
a first computer including a first operating system to execute on the first computer;
a second computer physically separate from the first computer and including a second operating system to execute on the second computer;
a screen to display information; and
a switch coupled to the first computer, the second computer, and the screen to selectively connect one of the first computer to the screen to display information from the first operating system of the first computer on the screen without waiting to load the first operating system on the first computer and the second computer to the screen to display information from the second operating system of the second computer on the screen without waiting to load the second operating system on the second computer.

2. The system of claim 1, further comprising a storage device coupled to both the first computer and the second computer on which the first and second operating systems are loaded.

3. The system of claim 1, wherein the first computer includes a first processor, a first memory, and a first network controller, and further wherein the second computer includes a second processor, a second memory, and a second network controller.

4. The system of claim 1, wherein the computer includes a voltage regulator module to supply power to the second computer.

5. The system of claim 4, wherein the voltage regulator module of the first computer is coupled to the second computer to supply power to the second computer.

6. The system of claim 1, wherein the first computer includes a port, and further wherein the second computer includes a housing that includes a plug to mechanically and electrically connect to the first computer via the port.

7. A system, comprising:
a first computer including a port and a first operating system to execute on the first computer;
a second computer coupled to the port of the first computer to receive power from the first computer and including a second operating system to simultaneously execute on the second computer; and
a circuit to selectively switch between a first context supported by the first operating system of the first computer and a second context supported by the second operating system of the second computer without waiting to save the first and second contexts.

8. The system of claim 7, further comprising a display coupled to the circuit, and wherein the circuit includes a component to selectively switch between a first video stream from the first operating system and a second video stream from the second operating system.

9. The system of claim 7, wherein the second computer includes a housing that includes a plug to mechanically and electrically connect to the first computer via the port of the first computer.

10. The system of claim 7, further comprising a storage device coupled to both the first computer and the second computer on which the first and second operating systems are loaded.

11. The system of claim 7, wherein the first computer includes a first processor, a first memory, and a first network controller, and further wherein the second computer includes a second processor, a second memory, and a second network controller.

12. The system of claim 7, wherein the first computer includes a voltage regulator module to supply power to the second computer.

13. The system of claim 12, wherein the voltage regulator module of the first computer is coupled to the second computer via the port to supply power to the second computer.

14. A method, comprising:
executing a first operating system on a first computer;
simultaneously executing a second operating system on a second computer;
switching from the first operating system executing on the first computer to select the second operating system executing on the second computer without delay caused by loading the second operating system into memory of the second computer and by saving a first context supported by the first operating system; and
switching from the second operating system executing on the second computer to select the first operating system executing on the first computer without delay caused by loading the first operating system into memory of the first computer and by saving a second context supported by the second operating system.

15. The method of claim 14, further comprising:
switching from a first video stream from the first operating system to a second video stream from the second operating system when switching from the first operating system executing on the first computer to the second operating system executing on the second computer; and
switching from the second video stream from the second operating system to the first video stream from the first operating system when switching from the second operating system executing on the second computer to the first operating system executing on the first computer.
